(19) United States
(12) Patent Application Publication
(10) Pub. No.: US 2026/0344241 A1
(43) Pub. Date: Oct. 29, 2026

(54) ELECTRONIC DEVICE

(71) Applicant: Innolux Corporation, Miaoli County (TW)

(72) Inventors: Yung-Hsin Lu, Miaoli County (TW); Jian-Min Leu, Miaoli County (TW); Yu-Shih Tsou, Miaoli County (TW); Yung-Hsun Wu, Miaoli County (TW)

(73) Assignee: Innolux Corporation, Miaoli County (TW)

(21) Appl. No.: 19/632,405

(22) Filed: Mar. 29, 2026

(30) Foreign Application Priority Data
Apr. 23, 2025 (CN) 202510516959.9

(51) Int. Cl. H10K 59/50; H10K 59/80

(52) U.S. Cl. CPC H10K 59/50; H10K 59/878

(57) ABSTRACT

An electronic device is provided. The electronic device has a first side and a second side opposite to the first side, and includes a dimming structure and a light emitting structure overlapping the dimming structure. In a frame time, the light emitting structure displays a first image during a first period in the frame time, and the light emitting structure displays a second image during a second period in the frame time, wherein the first image is observed from the first side, and the second image is observed from the second side.

### CROSS-REFERENCE TO RELATED APPLICATION

This application claims the priority benefit of China application serial no. 202510516959.9, filed on Apr. 23, 2025. The entirety of the above-mentioned patent application is hereby incorporated by reference herein and made a part of this specification.

### BACKGROUND

### Technical Field

The disclosure relates to an electronic device, and more particularly to an electronic device having a transmission region and a light emission region.

### Description of Related Art

In general, a transparent display having a dual-side display function is formed by joining two transparent displays together so as to respectively present a front image and a rear image. However, this approach requires more display elements and circuits.

### SUMMARY

An embodiment of the disclosure provides an electronic device, which has a first side and a second side opposite to the first side and includes a dimming structure and a light emitting structure overlapping the dimming structure. In a frame time, the light emitting structure displays a first image during a first period in the frame time, and the light emitting structure displays a second image during a second period in the frame time. The first image is observed from the first side, and the second image is observed from the second side.

To make the features and advantages of the disclosure more comprehensible, several embodiments accompanied with drawings are described in detail as follows.

### BRIEF DESCRIPTION OF THE DRAWINGS

The drawings are included for further understanding of the disclosure, and the drawings are incorporated into and constitute a part of the present specification. The drawings illustrate embodiments of the disclosure and, together with the description, are used to explain the principles of the disclosure.

FIG. 1 is a schematic side view of an electronic device according to an embodiment of the disclosure.

FIG. 2A is a schematic sectional view during a first period in a frame time according to a first embodiment of the disclosure.

FIG. 2B is a schematic sectional view during a second period in the frame time according to the first embodiment of the disclosure.

FIG. 2C is a schematic sectional view during a third period in the frame time according to the first embodiment of the disclosure.

FIG. 3A is a schematic sectional view during a first period in a frame time according to a second embodiment of the disclosure.

FIG. 3B is a schematic sectional view during a second period in the frame time according to the second embodiment of the disclosure.

FIG. 4A is a schematic sectional view during one period in a frame time according to a third embodiment of the disclosure.

FIG. 4B is a schematic sectional view during another period in the frame time according to the third embodiment of the disclosure.

FIG. 5 is a flowchart of manufacturing an electronic device according to an embodiment of the disclosure.

FIG. 6 is a flowchart of manufacturing an electronic device according to another embodiment of the disclosure.

### DESCRIPTION OF THE EMBODIMENTS

The disclosure may be understood by referring to the following detailed description in conjunction with the drawings. It should be noted that, in order to allow readers to easily understand and for the sake of simplicity of the drawings, multiple drawings in the disclosure show just a part of a package structure, and specific elements in the drawings are not drawn according to actual proportions.

Throughout the present specification and the appended claims, certain terms are used to refer to specific elements. A person skilled in the art should understand that manufacturers of electronic devices may refer to the same elements by different names. This document does not intend to distinguish elements that have the same function but different names. In the following description and the claims, words such as “have” and “comprise” are open-ended terms, and therefore should be interpreted as meaning “including but not limited to...”.

Directional terms mentioned in the present document, such as “upper,” “lower,” “front,” “rear,” “left,” “right,” and the like, are for referencing the directions shown in the drawings. Therefore, the directional terms used are for explanation and are not intended to limit the disclosure. It should be understood that when an element or a film layer is described as being “on” another element or film layer or “connected to” another element or film layer, the element or film layer may be directly on or directly connected to the another element or film layer, or there may be an intervening element or film layer (i.e., an indirect case) between the two. Conversely, when an element or film layer is described as being “directly” on another element or film layer or “directly connected to” another element or film layer, no intervening element or film layer exists between the two.

In the following embodiments, the same or similar elements will be denoted by the same or similar reference numerals, and redundant descriptions thereof will be omitted. Furthermore, the terms “first,” “second,” and the like mentioned in the present specification or the claims are merely used to designate different elements or distinguish different embodiments or ranges, and are not intended to limit an upper or lower limit on the number of elements, nor are they intended to limit a manufacturing sequence or arrangement order of elements.

The electronic device described in the disclosure may be applied to a light emitting device, a display device, and/or an automation apparatus, but is not limited thereto. The display device may include liquid crystal, light emitting diode (LED), other suitable materials, or a combination of the above. The light emitting diode may include an organic light emitting diode (OLED), micro-LED, mini-LED, or a quantum dot light emitting diode (QLED, QDLED).

The following provides exemplary embodiments of the disclosure. The same reference symbols in the drawings and the description are used to represent the same or similar parts.

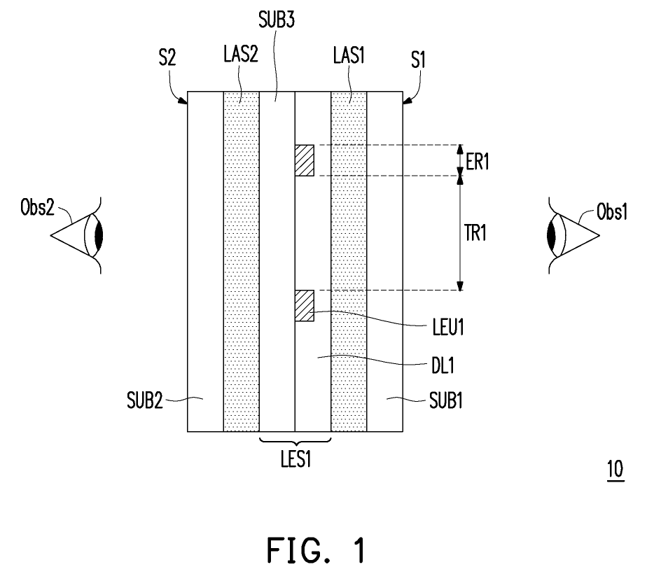

Please refer to FIG. 1. An electronic device 10 has a first side S1 and a second side S2 opposite to the first side S1 and includes a dimming structure LAS1 (or a dimming structure LAS2) and a light emitting structure LES1 overlapping the dimming structure LAS1 or LAS2. In this embodiment, in a frame time, the light emitting structure LES1 displays a first image observed from the first side S1 during a first period in the frame time, and the light emitting structure LES1 displays a second image observed from the second side S2 during a second period in the frame time. Therefore, the number of elements and circuits used to implement a dual-side display function may be reduced, so that the electronic device 10 is able to support the dual-side display function while also reducing the impact on an aperture ratio of a transmission region TR1. In this embodiment, the dimming structure LAS1 or LAS2 may be configured as a structure that controls light to pass through or blocks light. In the disclosure, the “frame time” is a time for displaying one image. For example, when a refresh rate of the electronic device is 60 Hz, one frame time is 1/60 second. The “overlap” in the disclosure refers to, for example, two objects overlapping in a viewing direction, or refers to the dimming structure (LAS1 or LAS2) overlapping in a direction toward the light emitting structure LES1.

In this embodiment, the electronic device 10 may include a dimming structure LAS1 and another dimming structure LAS2, wherein the dimming structure LAS1 is close to the first side S1, the another dimming structure LAS2 is close to the second side S2, and the light emitting structure LES1 is located between the dimming structure LAS1 and the another dimming structure LAS2. In this embodiment, the dimming structure LAS1 may be disposed between a substrate SUB1 and the light emitting structure LES1, and the another dimming structure LAS2 may be disposed between a substrate SUB2 and the light emitting structure LES1. The substrate SUB1 and the substrate SUB2 may each include any suitable transparent substrate material, such as a glass substrate or another flexible substrate, but the disclosure is not limited thereto. The dimming structure LAS1 and the another dimming structure LAS2 may each include dimming structures such as an electro-optic dimming structure, an electrowetting dimming structure, or a dye liquid crystal dimming structure.

In this embodiment, the light emitting structure LES1 may include a substrate SUB3, a plurality of light emitting units LEU1 disposed on the substrate SUB3, and a dielectric layer DL1 disposed on the substrate SUB3 and covering the light emitting units LEU1. The substrate SUB3 may include any suitable transparent substrate material, such as a glass substrate or another flexible substrate, but the disclosure is not limited thereto. The light emitting units LEU1 may include light emitting elements. The light emitting elements may include a light emitting diode (LED), but is not limited thereto. The dielectric layer DL1 may include an inorganic material, an organic material, or a combination of the foregoing, but is not limited thereto.

In this embodiment, the electronic device 10 may include a light emission region ER1 in which the light emitting units LEU1 are configured and a transmission region TR1 between the plurality of light emitting units LEU1. In this embodiment, light generated by the light emitting units LEU1 may be incident to an observer Obs1 and an observer Obs2 respectively through the first side S1 and the second side S2. In this embodiment, the transmission region TR1 may refer to a region in the entire electronic device 10 that allows ambient light to pass through, and a region in which light-blocking film layers, wirings, and elements are formed is not included in the transmission region as defined in this embodiment.

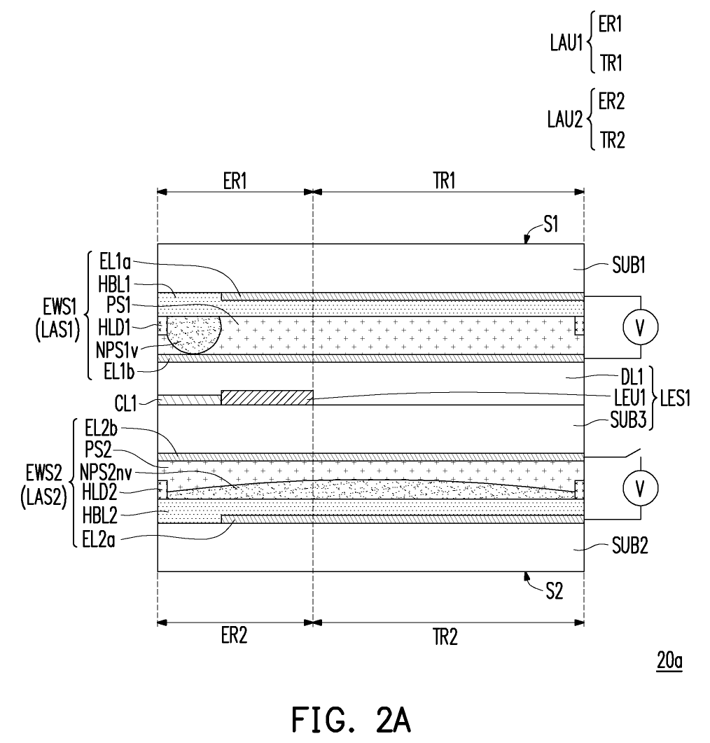

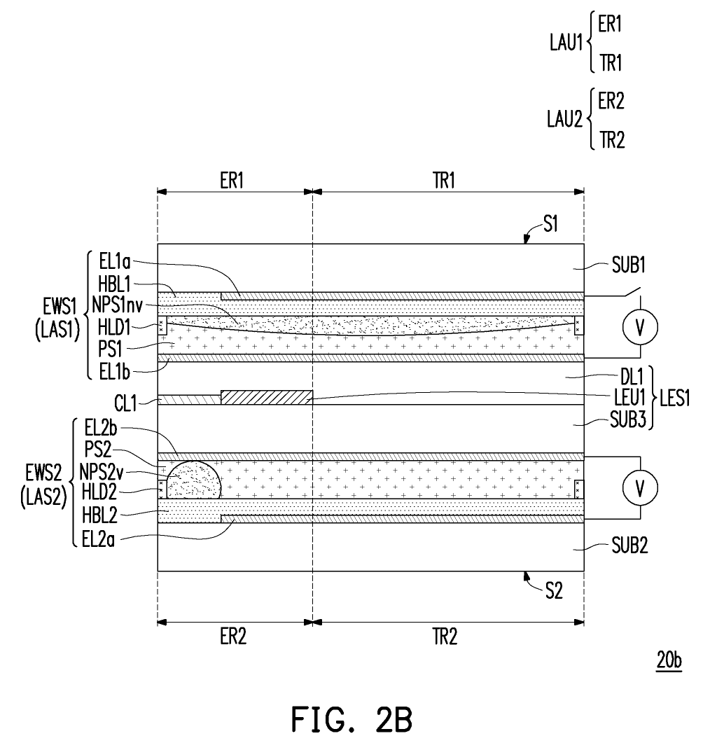

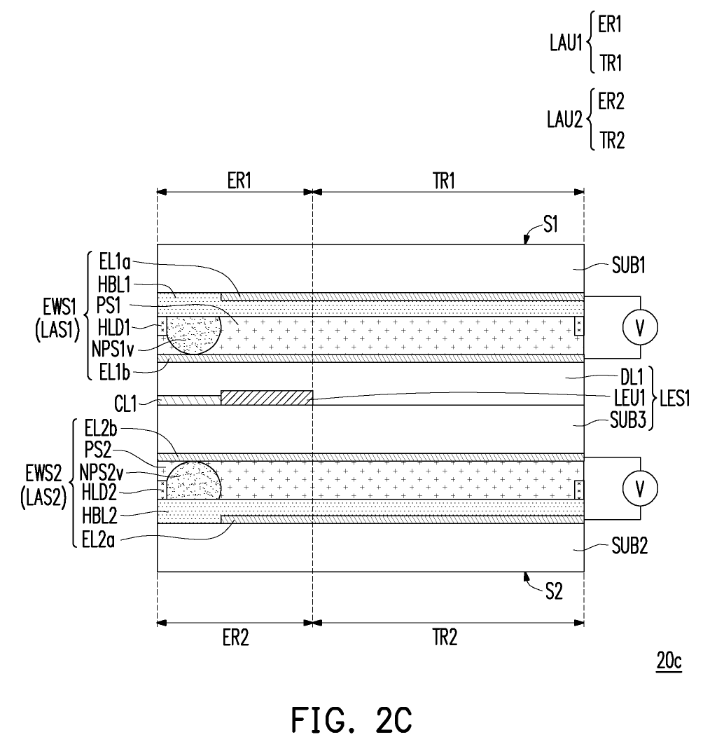

In the first embodiment, please refer to FIGS. 1 and 2A to 2C. The dimming structure LAS1 may include a plurality of first dimming units LAU1, wherein each of the first dimming units LAU1 includes a first light emission region ER1 and a first transmission region TR1. The another dimming structure LAS2 may include a plurality of second dimming units LAU2, wherein each of the second dimming units may include a second light emission region ER2 and a second transmission region TR2. The plurality of first dimming units LAU1 and the plurality of second dimming units LAU2 may be respectively disposed corresponding to the plurality of light emitting units LEU1. Therefore, a desired display effect may be achieved by individually controlling the first dimming units LAU1 and the second dimming units LAU2. In this embodiment, as shown in FIGS. 2A to 2C, the first light emission region ER1 may overlap the second light emission region ER2, and the first transmission region TR1 may overlap the second transmission region TR2.

In the first embodiment, please refer to FIGS. 2A to 2C. The dimming structure LAS1 may include a first electrowetting dimming structure EWS1, and the another dimming structure LAS2 may include a second electrowetting dimming structure EWS2. The first electrowetting dimming structure EWS1 may include a first non-polar solution (for example, NPS1v and NPS1nv), and the second electrowetting dimming structure EWS2 may include a second non-polar solution (for example, NPS2v and NPS2nv). The first non-polar solutions NPS1v and NPS1nv and the second non-polar solutions NPS2v and NPS2nv may each include non-polar solutions such as ink, but the disclosure is not limited thereto.

In the first embodiment, the first electrowetting dimming structure EWS1 may include a first electrode pattern EL1a disposed on a substrate SUB1, a first hydrophobic layer HBL1 disposed on the substrate SUB1 and covering the first electrode pattern EL1a, a first hydrophilic wall HLD1 disposed on the first hydrophobic layer HBL1, a first polar solution PS1, and first non-polar solutions NPS1v and NPS1nv, and a first electrode layer EL1b disposed above the first hydrophobic layer HBL1, wherein the first polar solution PS1 and the first non-polar solutions NPS1v and NPS1nv are sandwiched between the first hydrophobic layer HBL1 and the first electrode layer EL1b, and the first non-polar solutions NPS1v and NPS1nv are configured in a region defined by the first hydrophilic wall HLD1.

In the first embodiment, the second electrowetting dimming structure EWS2 may include a second electrode pattern EL2a disposed on a substrate SUB2, a second hydrophobic layer HBL2 disposed on the substrate SUB2 and covering the second electrode pattern EL2a, a second hydrophilic wall HLD2 disposed on the second hydrophobic layer HBL2, a second polar solution PS2, and second non-polar solutions NPS2v and NPS2nv, and a second electrode layer EL2b disposed above the second hydrophobic layer HBL2, wherein the second polar solution PS2 and the second non-polar solutions NPS2v and NPS2nv are sandwiched between the second hydrophobic layer HBL2 and the second electrode layer EL2b, and the second non-polar solutions NPS2v and NPS2nv are configured in a region defined by the second hydrophilic wall HLD2.

The first electrode pattern EL1a, the first electrode layer EL1b, the second electrode pattern EL2a, and the second electrode layer EL2b may each include any suitable transparent electrode material, but the disclosure is not limited thereto.

The first hydrophobic layer HBL1 and the second hydrophobic layer HBL2 may each include any suitable hydrophobic material. For example, the first hydrophobic layer HBL1 and the second hydrophobic layer HBL2 may be a fluoropolymer layer, a diamond-like carbon layer, or a self-assembled monolayer, but the disclosure is not limited thereto.

The first hydrophilic wall HLD1 and the second hydrophilic wall HLD2 may each include any suitable hydrophilic material, but the disclosure is not limited thereto.

The first polar solution PS1 and the second polar solution PS2 may each include any suitable polar solution, such as water or an aqueous solution containing an electrolyte, but the disclosure is not limited thereto. The first non-polar solutions NPS1v and NPS1nv and the second non-polar solutions NPS2v and NPS2nv may each include any suitable non-polar solution, such as a non-polar solution like ink, but the disclosure is not limited thereto.

FIG. 2A shows a state of an electronic device 20a during a first period in a frame time. As shown in FIG. 2A, a bias voltage is provided between the first electrode pattern EL1a and the first electrode layer EL1b, such that an electrowetting phenomenon is generated on the first hydrophobic layer HBL1 in a region overlapping the first electrode pattern EL1a and the first electrode layer EL1b (i.e., a region in which an electric field is distributed), causing the first non-polar solution NPS1v to be pushed by the first polar solution PS1 to a region of the first hydrophobic layer HBL1 without electric field distribution (for example, pushed to a region not overlapping the first electrode pattern EL1a). This way, the first non-polar solution NPS1v during the first period may overlap the first light emission region ER1 and not overlap the first transmission region TR1, and the first non-polar solution NPS1v does not overlap the light emitting unit LEU1. On the other hand, as shown in FIG. 2A, no bias voltage is provided between the second electrode pattern EL2a a v nd the second electrode layer EL2b, such that no electrowetting phenomenon caused by electric field distribution is generated on the second hydrophobic layer HBL2 in the second light emission region ER2 and the second transmission region TR2. Therefore, the second non-polar solution NPS2nv spreads on the second hydrophobic layer HBL2 to overlap the second light emission region ER2 and the second transmission region TR2. This way, the electronic device 20a may display a first image observed from the first side S1 during the first period, and ambient light from the second side S2 may be blocked by the second non-polar solution NPS2nv, thereby helping reduce interference with the first image caused by ambient light from the second side S2.

In this embodiment, the electronic device 20a may further include a circuit layer CL1 electrically connected to the light emitting unit LEU1. In this embodiment, the circuit layer CL1 may be configured to not overlap the light emitting unit LEU1. This way, an influence of wirings in the circuit layer CL1 on light emitted by the light emitting unit LEU1 toward the first side S1 and/or the second side S2 may be reduced. In this embodiment, the first non-polar solution NPS1v during the first period may overlap the circuit layer CL1 and not overlap the light emitting unit LEU1.

FIG. 2B shows a state of an electronic device 20b during a second period in a frame time. As shown in FIG. 2B, a bias voltage is provided between the second electrode pattern EL2a and the second electrode layer EL2b, such that an electrowetting phenomenon is generated on the second hydrophobic layer HBL2 in a region overlapping the second electrode pattern EL2a and the second electrode layer EL2b (i.e., a region in which an electric field is distributed), causing the second non-polar solution NPS2v to be pushed by the second polar solution PS2 to a region of the second hydrophobic layer HBL2 without electric field distribution (for example, pushed to a region not overlapping the second electrode pattern EL2a). This way, the second non-polar solution NPS2v during the second period may overlap the second light emission region ER2 and not overlap the second transmission region TR2, and the second non-polar solution NPS2v does not overlap the light emitting unit LEU1. On the other hand, as shown in FIG. 2B, no bias voltage is provided between the first electrode pattern EL1a and the first electrode layer EL1b, such that no electrowetting phenomenon caused by electric field distribution is generated on the first hydrophobic layer HBL1 in the first light emission region ER1 and the first transmission region TR1. Therefore, the first non-polar solution NPS1nv spreads on the first hydrophobic layer HBL1 to overlap the first light emission region ER1 and the first transmission region TR1. This way, the electronic device 20b may display a second image observed from the second side S2 during the second period, and ambient light from the first side S1 may be blocked by the first non-polar solution NPS1nv, thereby helping reduce interference with the second image caused by ambient light from the first side S1.

FIG. 2C shows a state of an electronic device 20c during a third period in a frame time. As shown in FIG. 2C, a bias voltage is provided between the first electrode pattern EL1a and the first electrode layer EL1b, such that an electrowetting phenomenon is generated on the first hydrophobic layer HBL1 in a region overlapping the first electrode pattern EL1a and the first electrode layer EL1b (i.e., a region in which an electric field is distributed), causing the first non-polar solution NPS1v to be pushed by the first polar solution PS1 to a region of the first hydrophobic layer HBL1 without electric field distribution (for example, pushed to a region not overlapping the first electrode pattern EL1a). This way, the first non-polar solution NPS1v during the third period may overlap the first light emission region ER1 and not overlap the first transmission region TR1. On the other hand, as shown in FIG. 2C, a bias voltage is provided between the second electrode pattern EL2a and the second electrode layer EL2b, such that an electrowetting phenomenon is generated on the second hydrophobic layer HBL2 in a region overlapping the second electrode pattern EL2a and the second electrode layer EL2b (i.e., a region in which an electric field is distributed), causing the second non-polar solution NPS2v to be pushed by the second polar solution PS2 to a region of the second hydrophobic layer HBL2 without electric field distribution (for example, pushed to a region not overlapping the second electrode pattern EL2a). This way, the second non-polar solution NPS2v during the third period may overlap the second light emission region ER2 and not overlap the second transmission region TR2. That is, when the electronic device 20c is in the third period in the frame time, the electronic device 20c may be in a state of a transparent display having a dual-side display function, which may present a first image and a second image on the first side S1 and the second side S2. Alternatively, the electronic device 20c may display an image on the first side S1 formed from ambient light originating from the second side S2, and display an image on the second side S2 formed from ambient light originating from the first side S1, that is, be in a window state.

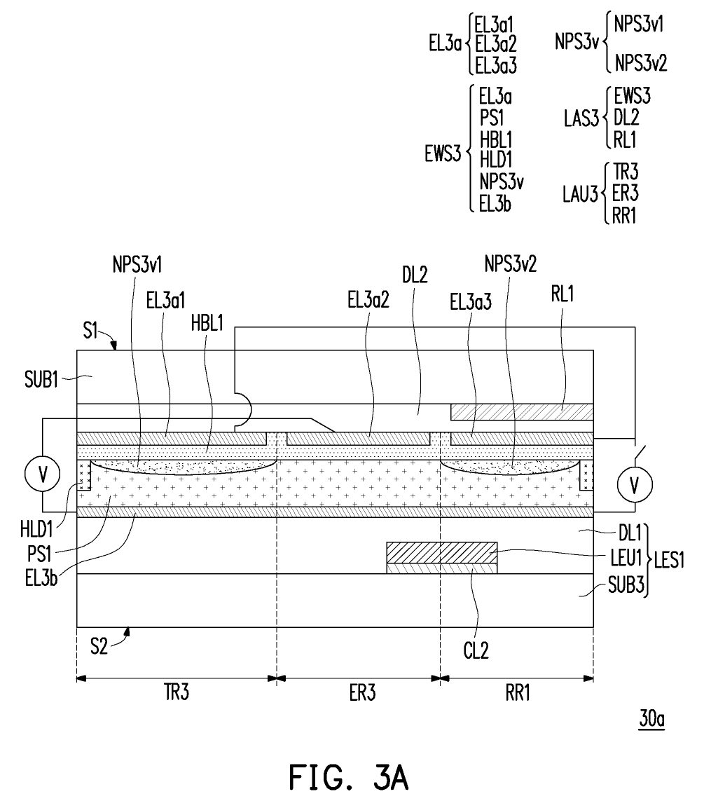

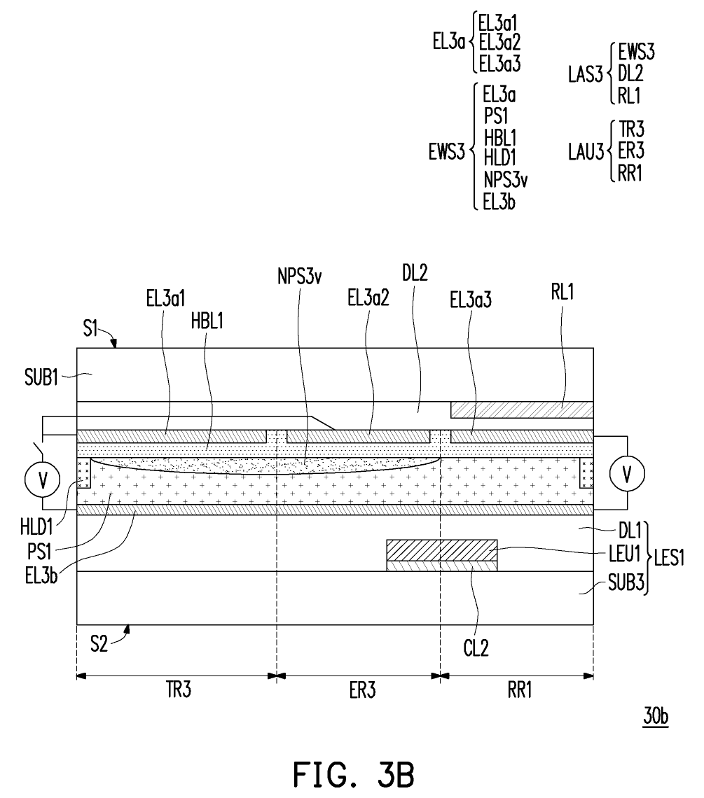

FIG. 3A is a schematic sectional view during a first period in a frame time according to a second embodiment of the disclosure. FIG. 3B is a schematic sectional view during a second period in the frame time according to the second embodiment of the disclosure. An electronic device 30a of the second embodiment shown in FIG. 3A is similar to the electronic device 20a of the first embodiment shown in FIG. 2A, with the main difference being that a dimming structure LAS3 of the electronic device 30a is different from the dimming structure LAS1 of the electronic device 20a, and the another dimming structure LAS2 is not included in the electronic device 30a. Other same or similar elements are indicated by same or similar element symbols, and redundant descriptions thereof are omitted.

In the second embodiment, please refer to FIGS. 1 and 3A and 3B. The dimming structure LAS3 may include a plurality of dimming units LAU3 disposed corresponding to the plurality of light emitting units LEU1, wherein each dimming unit LAU3 includes a light emission region ER3, a transmission region TR3, and a reflection region RR1. In this embodiment, the dimming structure LAS3 may include a reflective layer RL1 disposed in the reflection region RR1 and a dielectric layer DL2 disposed on a substrate SUB1 and covering the reflective layer RL1. The reflective layer RL1 may include any suitable material for reflecting light, such as a metal material like aluminum or silver, or a metal oxide like titanium oxide, but the disclosure is not limited thereto. The dielectric layer DL2 may include an inorganic material, an organic material, or a combination of the foregoing, but is not limited thereto.

In the second embodiment, please refer to FIGS. 3A and 3B. The dimming structure LAS3 may include an electrowetting dimming structure EWS3, wherein the electrowetting dimming structure EWS3 may include a non-polar solution NPS3v. The non-polar solution NPS3v may include a non-polar solution such as ink, but the disclosure is not limited thereto.

In the second embodiment, the electrowetting dimming structure EWS3 may include an electrode pattern EL3a disposed on a substrate SUB1, a hydrophobic layer HBL1 disposed on the substrate SUB1 and covering the electrode pattern EL3a, a hydrophilic wall HLD1 disposed on the hydrophobic layer HBL1, a polar solution PS1, a non-polar solution NPS3v, and an electrode layer EL3b disposed above the hydrophobic layer HBL1, wherein the polar solution PS1 and the non-polar solution NPS3v are sandwiched between the hydrophobic layer HBL1 and the electrode layer EL3b, and the non-polar solution NPS3v is configured in a region defined by the hydrophilic wall HLD1. In this embodiment, the electrode pattern EL3a may include a first part EL3a1, a second part EL3a2, and a third part EL3a3 that are separated from one another in a horizontal direction.

FIG. 3A shows a state of the electronic device 30a during a first period in a frame time. As shown in FIG. 3A, a bias voltage is provided between the second part EL3a2 of the electrode pattern EL3a and the electrode layer EL3b, and no bias voltage is provided between the first part EL3a1 of the electrode pattern EL3a and the electrode layer EL3b, and between the third part EL3a3 of the electrode pattern EL3a and the electrode layer EL3b, such that an electrowetting phenomenon is generated on the hydrophobic layer HBL1 in a region overlapping the second part EL3a2 of the electrode pattern EL3a, causing the non-polar solution NPS3v to be pushed by the polar solution PS1 to both sides of the second part EL3a2 of the electrode pattern EL3a, including a first part MPS3v1 overlapping the first part EL3a1 of the electrode pattern EL3a and a second part MPS3v2 overlapping the third part EL3a3 of the electrode pattern EL3a. That is, the non-polar solution NPS3v during the first period may overlap the reflection region RR1 and the transmission region TR3 and not overlap the light emission region ER3. This way, the electronic device 30a may display a first image observed from the first side S1 during the first period.

In this embodiment, the electronic device 30a may further include a circuit layer CL2 electrically connected to the light emitting unit LEU1. In this embodiment, the circuit layer CL2 may be configured to overlap the light emitting unit LEU1.

FIG. 3B shows a state of an electronic device 30b during a second period in a frame time. As shown in FIG. 3B, a bias voltage is provided between the third part EL3a3 of the electrode pattern EL3a and the electrode layer EL3b, and no bias voltage is provided between the first part EL3a1 of the electrode pattern EL3a and the electrode layer EL3b, and between the second part EL3a2 of the electrode pattern EL3a and the electrode layer EL3b, such that an electrowetting phenomenon is generated on the hydrophobic layer HBL1 in a region overlapping the third part EL3a3 of the electrode pattern EL3a, causing the non-polar solution NPS3v to be pushed by the polar solution PS1 to a region not overlapping the third part EL3a3 of the electrode pattern EL3a. That is, the non-polar solution NPS3v during the second period may overlap the transmission region TR3 and the light emission region ER3 and not overlap the reflection region RR1. This way, the electronic device 30b may display a second image observed from the second side S2 during the second period through the reflective layer RL1 in the reflection region RR1. In other embodiments, the frame time may further include a third period. In the third period, a bias voltage may be provided between the first part EL3a1 of the electrode pattern EL3a and the electrode layer EL3b, and no bias voltage may be provided between the third part EL3a3 of the electrode pattern EL3a and the electrode layer EL3b and between the second part EL3a2 of the electrode pattern EL3a and the electrode layer EL3b. At this time, the electronic device is in a transmission state, but the disclosure is not limited thereto.

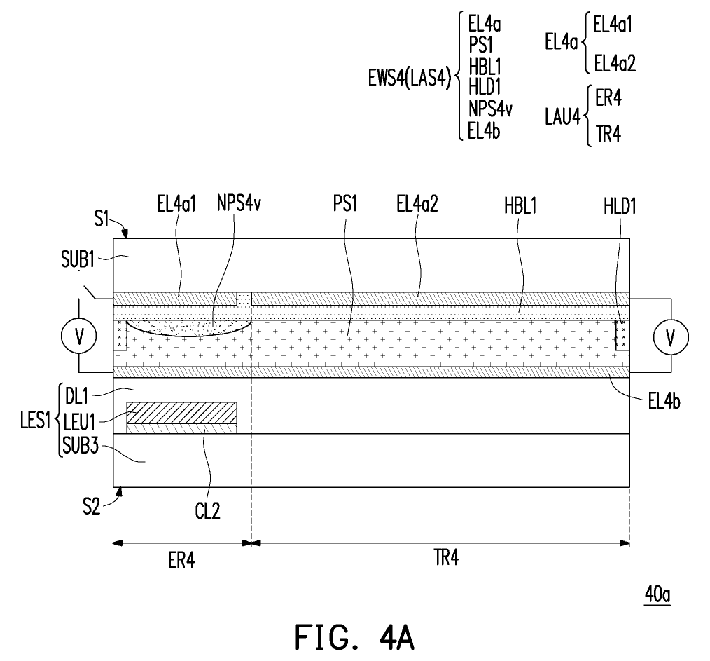

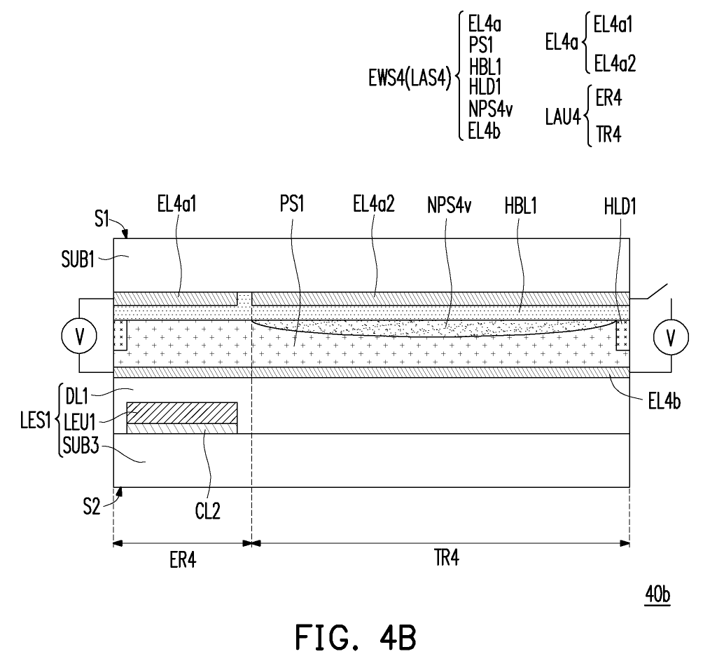

An electronic device 40a of the third embodiment shown in FIG. 4A is similar to the electronic device 20a of the first embodiment shown in FIG. 2A, with the main difference being that a dimming structure LAS4 of the electronic device 40a is different from the dimming structure LAS1 of the electronic device 20a, and the another dimming structure LAS2 is not included in the electronic device 40a. Other same or similar elements are indicated by same or similar element symbols, and redundant descriptions thereof are omitted.

In the third embodiment, please refer to FIGS. 1 and 4A and 4B. The dimming structure LAS4 may include a plurality of dimming units LAU4 disposed corresponding to the plurality of light emitting units LEU1, wherein each dimming unit LAU4 includes a light emission region ER4 and a transmission region TR4. In this embodiment, the dimming structure LAS4 may include an electrowetting dimming structure EWS4, wherein the electrowetting dimming structure EWS4 may include a non-polar solution NPS4v. The non-polar solution NPS4v may include a non-polar solution such as ink, but the disclosure is not limited thereto.

In the third embodiment, the electrowetting dimming structure EWS4 may include an electrode pattern EL4a disposed on a substrate SUB1, a hydrophobic layer HBL1 disposed on the substrate SUB1 and covering the electrode pattern EL4a, a hydrophilic wall HLD1 disposed on the hydrophobic layer HBL1, a polar solution PS1 and a non-polar solution NPS4v, and an electrode layer EL4b disposed above the hydrophobic layer HBL1, wherein the polar solution PS1 and the non-polar solution NPS4v are sandwiched between the hydrophobic layer HBL1 and the electrode layer EL4b, and the non-polar solution NPS4v is configured in a region defined by the hydrophilic wall HLD1. In this embodiment, the electrode pattern EL4a may include a first part EL4a1 and a second part EL4a2 that are separated from one another in a horizontal direction.

FIG. 4A shows a state of the electronic device 40a during one period in a frame time. As shown in FIG. 4A, a bias voltage is provided between the second part EL4a2 of the electrode pattern EL4a and the electrode layer EL4b, and no bias voltage is provided between the first part EL4a1 of the electrode pattern EL4a and the electrode layer EL4b, such that an electrowetting phenomenon is generated on the hydrophobic layer HBL1 in a region overlapping the second part EL4a2 of the electrode pattern EL4a, causing the non-polar solution NPS4v to be pushed by the polar solution PS1 to a region not overlapping the second part EL4a2 of the electrode pattern EL4a. That is, the non-polar solution NPS4v during the period may overlap the light emission region ER4 and not overlap the transmission region TR4. This way, the electronic device 40a may display an image formed from ambient light originating from the second side S2 on the first side S1, and display an image formed from ambient light originating from the first side S1 on the second side S2, that is, be in a window state.

FIG. 4B shows a state of an electronic device 40b during another period in a frame time. As shown in FIG. 4B, a bias voltage is provided between the first part EL4a1 of the electrode pattern EL4a and the electrode layer EL4b, and no bias voltage is provided between the second part EL4a2 of the electrode pattern EL4a and the electrode layer EL4b, such that an electrowetting phenomenon is generated on the hydrophobic layer HBL1 in a region overlapping the first part EL4a1 of the electrode pattern EL4a, causing the non-polar solution NPS4v to be pushed by the polar solution PS1 to a region not overlapping the first part EL4a1 of the electrode pattern EL4a. That is, the non-polar solution NPS4v during the another period may overlap the transmission region TR4 and not overlap the light emission region ER4. This way, the electronic device 40b may display a first image observed from the first side S1 during the another period, and ambient light from the second side S2 may be blocked by the non-polar solution NPS4v, thereby helping reduce interference with the first image caused by ambient light from the second side S2.

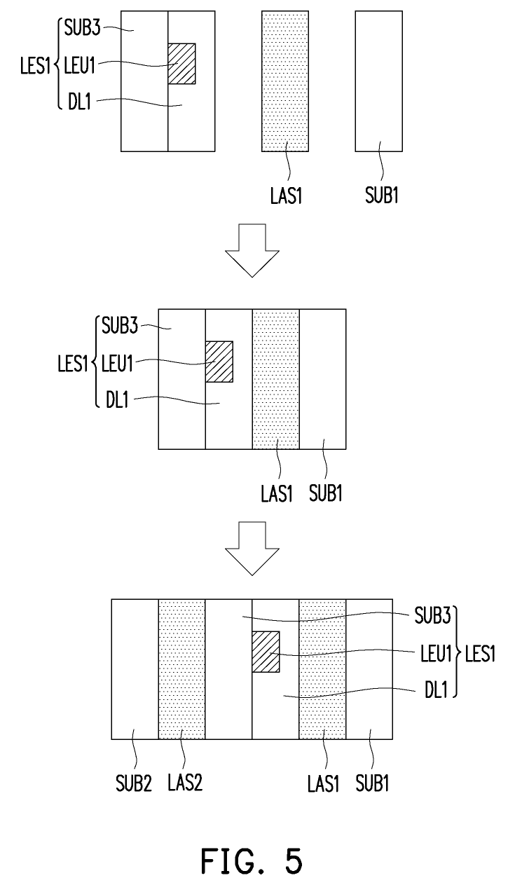

Please refer to FIG. 5. Manufacturing the electronic device may include the following steps. First, a light emitting structure LES1 is provided. Next, a dimming structure LAS1 is sandwiched between the light emitting structure LES1 and a substrate SUB1. In some embodiments, the dimming structure LAS1 may first be formed on one side of the light emitting structure LES1, and then the substrate SUB1 is laminated over the dimming structure LAS1, but the disclosure is not limited thereto. In other embodiments, the dimming structure LAS1 may first be formed on the substrate SUB1, and then the dimming structure LAS1 formed on the substrate SUB1 is bonded to one side of the light emitting structure LES1. Thereafter, a dimming structure LAS2 formed on a substrate SUB2 is bonded to the other side of the light emitting structure LES1.

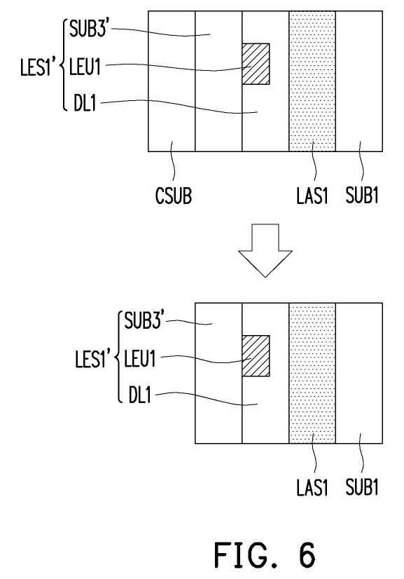

In other embodiments, as shown in FIG. 6, in an embodiment in which the light emitting units LEU1 are formed on a flexible substrate SUB3’, for example, a method of manufacturing the electronic device may include the following steps. First, a light emitting structure LES1’ is provided on a carrier substrate CSUB. Next, as described above, a dimming structure LAS1 is sandwiched between the light emitting structure LES1’ and a substrate SUB1. Then, the carrier substrate CSUB is removed. Thereafter, as shown in FIG. 5, a dimming structure LAS2 formed on a substrate SUB2 is bonded to another side of the light emitting structure LES1’.

In summary, in the electronic device of the embodiment of the disclosure, the light emitting structure displays a first image observed from a first side during a first period in a frame time, and displays a second image observed from a second side during a second period in the frame time. This way, the number of elements and circuits used to implement a dual-side display function may be reduced, so that the electronic device is capable of supporting the dual-side display function under a condition where an impact on an aperture ratio of the transmission region is reduced.

The above embodiments are used to illustrate the technical solution of the disclosure, and are not intended to limit the same. Although the disclosure has been described in detail with reference to the above embodiments, a person skilled in the art should understand that modifications may still be made to the technical solutions described in the above embodiments, or equivalent replacements may be made for some or all of the technical features. These modifications or replacements do not cause the essence of the corresponding technical solutions to depart from the scope of the technical solutions of the embodiments of the disclosure. The features among the embodiments may be arbitrarily combined and used as long as they do not violate or conflict with the spirit of the invention.

What is claimed is:

1. An electronic device, having a first side and a second side opposite to the first side, wherein the electronic device comprises:
a dimming structure; and
a light emitting structure, overlapping the dimming structure,
wherein, in a frame time, the light emitting structure displays a first image during a first period in the frame time, the light emitting structure displays a second image during a second period in the frame time, the first image is observed from the first side, and the second image is observed from the second side.

2. The electronic device according to claim 1, wherein the dimming structure comprises a plurality of dimming units, the light emitting structure comprises a plurality of light emitting units, the plurality of dimming units are respectively disposed corresponding to the plurality of light emitting units, and each dimming unit comprises a transmission region, a reflection region, and a light emission region.

3. The electronic device according to claim 2, wherein the dimming structure comprises a reflective layer configured in the reflection region.

4. The electronic device according to claim 2, wherein the dimming structure comprises an electrowetting dimming structure, and the electrowetting dimming structure comprises a non-polar solution, wherein:
in the first period, the non-polar solution overlaps the reflection region and the transmission region and does not overlap the light emission region; and
in the second period, the non-polar solution overlaps the transmission region and the light emission region and does not overlap the reflection region.

5. The electronic device according to claim 2, further comprising:
a circuit layer, electrically connected to each light emitting unit and configured to overlap each light emitting unit.

6. The electronic device according to claim 1, further comprising another dimming structure, wherein the dimming structure is close to the first side, the another dimming structure is close to the second side, and the light emitting structure is located between the dimming structure and the another dimming structure.

7. The electronic device according to claim 6, wherein the dimming structure comprises a plurality of first dimming units, the another dimming structure comprises a plurality of second dimming units, the light emitting structure comprises a plurality of light emitting units, and the plurality of first dimming units and the plurality of second dimming units are respectively disposed corresponding to the plurality of light emitting units, wherein
each first dimming unit comprises a first light emission region and a first transmission region, each of second dimming unit comprises a second light emission region and a second transmission region, the first light emission region overlaps the second light emission region, and the first transmission region overlaps the second transmission region.

8. The electronic device according to claim 7, wherein the dimming structure comprises a first electrowetting dimming structure, the another dimming structure comprises a second electrowetting dimming structure, the first electrowetting dimming structure comprises a first non-polar solution, and the second electrowetting dimming structure comprises a second non-polar solution, wherein:
in the first period, the first non-polar solution overlaps the first light emission region and does not overlap the first transmission region, and the second non-polar solution overlaps the second light emission region and the second transmission region.

9. The electronic device according to claim 8, wherein in the second period, the first non-polar solution overlaps the first light emission region and the first transmission region, and the second non-polar solution overlaps the second light emission region and does not overlap the second transmission region.

10. The electronic device according to claim 1, further comprising:
a circuit layer, electrically connected to each light emitting unit and configured to not overlap each light emitting unit.
